(19) United States
(12) Patent Application Publication
(10) Pub. No.: US 2020/0370169 A1
(43) Pub. Date: Nov. 26, 2020

(54) IMPROVED GUIDANCE OF IONS FROM A PLASMA TO A SUBSTRATE TO BE COATED

(71) Applicant: Robert Bosch GmbH, Stuttgart (DE)

(72) Inventors: Oliver Schmidt, Hemmingen (DE); Marcus Guenther, Gerlingen (DE); Wladislaw Dobrygin, Stuttgart (DE)

(21) Appl. No.: 16/319,659

(22) PCT Filed: Jun. 21, 2017
(86) PCT No.: PCT/EP2017/065185

§ 371 Date: Jan. 22, 2019

(30) Foreign Application Priority Data
Jul. 28, 2016 (DE) 10 2016 213 951.7

(51) Int. Cl. C23C 14/54; C23C 14/22; C23C 14/50; H01J 37/32

(52) U.S. Cl. CPC C23C 14/54; C23C 14/221; C23C 14/50; H01J 2237/0473; H01J 37/32403; H01J 37/32422; H01J 2237/332; H01J 37/32715

(57) ABSTRACT

The invention relates to a substrate holder (1) comprising a first contact (3) for the supply of a potential Uₛ to the substrate (2), a charging region (12) on the surface (11) of the substrate holder (1) being designed such that it can be charged (13) with ions (101, 102) from the ion source (104) of a coating facility (100), and/or a second contact (4) is provided by means of which a freely selectable potential U_{H} different from the potential Uₛ can be applied to an electrode region (14) on the surface (11) of the substrate holder (1). The invention also relates to a coating facility (100) comprising at least one ion source (104) and a first voltage source (106) that can be connected to the substrate to be coated (2) such that gas ions (101) and/or ions (102) of a coating material (103) can be accelerated in the direction of the substrate (2) from the ion source (104) by means of an electric potential Uₛ applied to the substrate (2) from the first voltage source (106), at least one secondary surface (11, 105), towards which ions (101, 102) missing the substrate (2) move, being designed (13, 113) such that it can be charged with arriving ions (101, 102), and/or at least one second voltage source (107) being provided, which can be connected to the secondary surface (11, 105) such that a freely selectable potential Uₛ different from the potential Uₛ can be applied to said secondary surface (11, 105). The invention further relates to an operating method and to a computer program product.

### BACKGROUND OF THE INVENTION

The present invention relates to a substrate holder and to a coating system for coating substrates with ions from a plasma, as well as to a method for operating a coating system.

In the vacuum coating of components on the industrial scale, a multiplicity of components to be coated simultaneously as substrates are grouped around a central plasma. The plasma functions as a source for the ions of the coating material. By applying a high voltage to the individual substrates, ions are accelerated in the direction of the substrates. Since the ions strike the substrates with high kinetic energies, a high-quality coating is formed there.

A corresponding apparatus is known from DE 198 26 259 A1. The separation of plasma generation and substrate voltage generation allows control of the substrate temperature as well as the use of different types of plasma generation sources. The substrate voltage is applied according to a bipolar-pulsed time program, in order to counteract charging effects.

JP 2001 107 729 A discloses, in a sputtering system, to apply a voltage not to the substrate itself but to an electrode buried in the insulating substrate holder. By interaction of this voltage with the plasma, the electric field on the substrate surface, and therefore also the coverage of the substrate with the layer applied, is homogenized.

JP 2000 119 849 A discloses mounting of the substrate on an insulating substrate holder, and simultaneous dissipation of charges from the substrate by applying a bias voltage to the substrate. In this way, stresses in the vapor-deposited thin films are reduced.

### SUMMARY OF THE INVENTION

In the scope of the invention, a substrate holder for mounting a substrate in a coating system has been developed. In this case, it is proposed that a surface of a substrate holder faces toward an ion source of the coating system. The substrate holder comprises a first contact for delivering a potential U_{S} to the substrate.

According to the invention, a charging region on the surface of the substrate holder is configured to be chargeable by ions incident from the ion source of the coating system, and/or a second contact is provided, by means of which a freely selectable potential U_{H} different to the potential U_{S} can be applied to an electrode region on the surface of the substrate holder. The potential U_{H} may, in particular, be a floating potential or a ground potential.

For example, an insulating material piece of the substrate holder may provide the charging region. In particular, the substrate holder may be made entirely of insulating material. The surface of the substrate holder may, however, also be electrically conductive. It may then, for example, be fully or partially provided with a covering. The covering may itself be insulating, or at least insulated from the surface of the substrate holder. The covering may for example comprise a dielectric layer, on which a metal layer may optionally also be arranged. The surface of the substrate holder may, however, for example also be electrically conductive and segmented into a plurality of mutually insulated regions in its plane. For example, the substrate holder may be made of a ceramic, on which the segmented electrically conductive surface is applied as a coating. A segment from which incident ions cannot flow away may then be used as a charging region.

If a region on an electrically conductive surface of the substrate is configured by a covering as a charging region, this region may in particular also be used at the same time as an electrode region.

It has been discovered that, by the charging region and the electrode region individually or in combination, the guidance of the ions from the plasma onto the substrate is improved. In particular, the proportion of ions striking the substrate may be increased, while at the same time the proportion of ions missing the substrate and striking secondary surfaces of the substrate holder or of the coating system is reduced.

Ions which strike secondary surfaces with high energy may separate atoms therefrom, which are deposited as impurities on the substrate. This relates, in particular, to the cleaning process before the actual coating, during which impurities are ablated from the surface of the substrate by bombardment with high-energy gas ions, for example argon ions, from the plasma used as an ion source. If these gas ions strike metallic secondary surfaces, for example, they may separate metal atoms therefrom, for example iron atoms.

At the same time, ions that miss the substrate and strike secondary surfaces are not available on the surface of the substrate. Regions of the substrate surface which do not lie in direct line of sight with the ion source are thus possibly undersupplied with ions. If the substrate is a complex component, which has for example undercuts, it possibly needs to be rotated or repositioned during the processing. This relates both to the cleaning and to the subsequent coating.

The substrate holder according to the invention provides two mutually independent design features, which counteract both undesired ablation of secondary surfaces during the cleaning and undersupply of regions of the substrate surface with ions.

A charging region on the surface of the substrate holder becomes charged during operation of the coating system by charged particles, in particular gas ions and/or ions of a coating material. Extending from this charge, there is an electric field which reduces the electric field in the free space between the ion source and the substrate holder overall. Ions from the ion source, which miss the substrate, are thus accelerated more weakly onto the substrate holder. Surprisingly, this has the effect that at least some of the ions which have already missed the substrate per se nevertheless still receive a sufficient momentum component in the direction of the substrate surface on the trajectory towards the substrate holder by statistical collision processes, and strike the substrate surface. The electric field originating from the charging of the charging region may, depending on its strength and the speed of the incident ions, even deviate these ions directly onto the substrate surface without statistical collision processes still being required therefor.

These effects may be caused solely by modification of the substrate holder, without design changes having to be carried out on the coating system itself. In particular, an existing coating system may be retrofitted with the substrate holder according to the invention, without the coating system itself having to satisfy particular requirements therefor.

According to the opinion so far prevailing in general technical knowledge, charging effects on system parts due to ions incoming from the ion source have merely been regarded as a perturbing effect to be avoided, which ought to be avoided. The substrate holder and other system parts, toward which the ions missing the substrate moved, therefore generally have been grounded so that the charges introduced by the ions could flow away. The Inventors have discovered that this supposed perturbing effect can be expediently used in order to improve the quality of the coating obtained.

If a charging region is provided on the surface of the substrate holder and an additional freely selectable potential U_{H} can be applied to it then the electric field between the ion source, the substrate and the substrate holder can be adapted to an even greater extent and with an even greater degree of freedom so that ions which have already missed the substrate per se are actively deviated in the direction of the surface of the substrate. The potential landscape may, in particular, be configured in such a way that the potential U_{S} on the surface of the substrate is at the lowest energy as seen by the ions and/or the ions are repelled by the substrate holder.

Besides the substrate holder, the invention also provides a coating system which is optimized for use with the substrate holder according to the invention, but even without this substrate holder still has advantages over conventional coating systems and may be sold as a separate unit.

This coating system comprises at least one ion source and a first voltage source, which can be connected to the substrate to be coated so that gas ions, and/or ions of the coating material, from the ion source can be accelerated in the direction of the substrate by an electrical potential U_{S} applied to the substrate by the first voltage source. In this case, the ion source may in particular be a plasma. The potential landscape in free space on the far side of the plasma boundary layer dictates the direction in which and the speed with which the ions move out of the plasma.

According to the invention, at least one secondary surface, toward which ions that miss the substrate move, is configured to be chargeable by incident ions. As an alternative or in combination, at least one second voltage source is provided, which can be connected to the secondary surface so that a freely selectable potential U_{H} different to the potential U_{S} can be applied to this secondary surface. In particular, the secondary surface may be configured to be chargeable in the same way as described above for the substrate holder. The potential U_{H} may, in particular, be a floating potential or a ground potential.

Depending on the geometry of the coating system, of the substrate and of the associated substrate holder, the secondary surface may be arranged on the substrate holder and/or at a different position inside the coating system. For example, some of the ions that miss the substrate may move toward the substrate holder and some others toward the wall of the vacuum container. Such a system may, for example, arise when a plasma as an ion source is arranged at the center of the coating system and the substrates to be coated are grouped around the plasma. The potential U_{S} applied to the substrates then attracts the ions from the plasma radially outward. If the substrate holders are fastened in the bottom or the top of the vacuum container, for example, ions that miss the substrates preferably move toward the side wall of the vacuum container.

The coating system on the one hand interacts with the substrate holder in such a way that the second voltage source in connection with the second contact of the substrate holder can apply the potential U_{H} to a part of the surface of the substrate holder. On the other hand, the probability of the incidence of ions that have missed the substrate on further secondary surfaces, not belonging to the substrate holder, by charging with the incident ions, by application of the potential U_{H}, or by a combination of the two measures, may also be reduced. The effect is respectively the same as described above for the substrate holder: the resulting electric field between the ion source, the substrate and the secondary surfaces is modified in such a way that incidence of ions on the secondary surfaces with high energy is prevented, and ideally the ions are deviated onto the substrate surface.

In another particularly advantageous configuration of the invention, a controller for the second voltage source is provided. This controller is advantageously configured in order to track the potential U_{H} to a change in the potential U_{S}, in such a way that the potential U_{S} is at a lower energy than the potential U_{H} as seen by the ions. As an alternative or in combination, the controller is configured in order to track the potential U_{H} to a change in properties of the ion reservoir, and/or to a change in the potential U_{S}, in such a way that the potential U_{H} is repulsive as seen by the ions.

The acceleration which the ions from the plasma experience in the direction of the substrate is attributable to an electrostatic force. This force depends on the potential difference between the plasma and the substrate, the so-called plasma boundary layer. The potential of the plasma boundary layer depends in turn on the properties of the plasma, for example on its composition, pressure and ionization. For instance, the plasma boundary layer of a pure argon plasma, as is used for cleaning the substrate before the actual coating, has a different potential than the plasma boundary layer of a plasma which additionally contains the actual coating material. In order to control the kinetic energy of the ions incident on the substrate, and therefore also the effect of the ions on the substrate, the potential U_{S} on the substrate is controlled as a process parameter. The controller then ensures that the potential U_{H} is constantly adapted in order to minimize the incidence of ions on secondary surfaces. In this way, in particular, it is possible to ensure that a change in the properties of the plasma, and/or of U_{S}, does not suddenly lead to an undersupply of regions of the substrate surface with ions.

In another particularly advantageous configuration of the invention, a substrate holder according to the invention is connected into the electrical connection between the first voltage source and the substrate, and/or into the electrical connection between the second voltage source and the secondary surface. For example, the first voltage source may be connected by means of the first contact of the substrate holder to the substrate, and/or the second voltage source may be connected by means of the second contact of the substrate holder to an electrode region of the substrate holder.

If a region on the substrate holder or on another secondary surface is configured to be chargeable with a dielectric coating or another insulating covering, then there is a minimum for the thickness of this dielectric coating, or insulating covering. This minimum is dictated by the material-dependent dielectric strength. The thickness should be selected in such a way that the breakdown field strength at each point is greater than the field strength in the coating or covering, which occurs because of the surface charging. The maximum thickness is limited by the perturbing contours of the substrate holder, for example neighboring substrate holders and/or system parts, or the plasma itself.

Depending on the application, it is thus possible to use thin coatings with thicknesses of a few micrometers, but also, for instance, insulations made of ceramic or polymer materials with thicknesses of up to several centimeters, in order to realize a charging region.

According to that stated above, the invention also relates to a method for operating a coating system, in which gas ions, and/or ions of a coating material, from an ion reservoir are accelerated in the direction of the substrate by applying an electrical potential U_{S} to a substrate.

According to the invention, a potential U_{H} different to the potential U_{S} is applied to at least one secondary surface, toward which ions that miss the substrate move. In this case, particularly, advantageously, a potential U_{H} is selected which has a repulsive effect on the ions. The consequence of this is that at least some of the ions are kept away from the secondary surface. The potential U_{H} may, in particular, be a floating potential or a ground potential.

A combination of potentials U_{S} and U_{H} is particularly advantageously selected, which deviates ions travelling in the direction of the secondary surface onto the substrate. In this way, in particular the surface of a complex component with undercuts, from which there is no direct line of sight in the direction of the ion source, can be processed fully without the component having to be rotated in the vacuum container or moved in another way. It is possible to save on corresponding outlay for mechanical and electrical feed-throughs into the vacuum container. This applies both for the actual coating and for the cleaning which precedes this coating. If, however, means are provided for moving the substrate in the coating system, this movement may advantageously cooperate with the measures according to the invention.

The potential landscape formed from the potential of the ion source, in cooperation with the potentials U_{S} and U_{H}, deviates ions as a function of their initial position and their initial momentum according to the laws of electrostatics in a deterministic way to a particular position on the surface of the substrate. Since the ion source, for instance a plasma, is spatially extended and the initial momentum of the ions has a distribution with a certain width, the incidence positions of the ions on the surface of the substrate are also distributed over a zone with a particular spatial extent. Nevertheless, especially in the case of large-format components as substrates, and/or in the case of a particularly complex geometry of the undercuts, parts of the surface may remain undersupplied with ions. In order to homogenize the total dose of ions over the surface of the substrate, especially in the region outside the direct line of sight with the ion source, in another particular advantageous configuration of the invention the potential U_{H} is varied in order to modify the position at which the deviated ions strike the substrate.

According to that stated above, the method develops particularly advantageous effects in conjunction with a coating system according to the invention, and/or with a coating system which contains a substrate holder according to the invention. That the coating system is a system according to the invention is, conversely, not a necessary condition for an improvement being achieved. The method is thus also an independent salable product, which may be added as an add-on to an existing coating system. For example, the functionality of the controller for the second voltage source may be embodied in this add-on.

The method may, in particular, be embodied in a computer program. The invention therefore also relates to a computer program product containing machine-readable instructions which, when they are executed on a computer and/or a control device with a coating system connected thereto, convert the coating system into a coating system according to the invention, and/or cause the computer, the control device and/or the coating system to carry out a method according to the invention.

The invention may particularly advantageously be used to deposit DLC wear protection layers, and therefore indirectly improves all the component parts of the injection-molding technique which uses such DLC layers. Furthermore, the invention may also be used in all low-pressure-based plasma coatings, in which the plasma generation on the one hand, and the acceleration of the ions by a bias voltage on the other hand, are decoupled from one another. This applies both in in-line systems and in batch manufacture. Examples of such applications are magnetron sputtering, an ECR source, a low-voltage arc or a different ion source.

Further measures that improve the invention will be presented in more detail below together with the description of the preferred exemplary embodiments of the invention with the aid of figures.

### BRIEF DESCRIPTION OF THE DRAWINGS

FIG. 1 shows an exemplary embodiment of a coating system 100 according to the invention;

FIG. 2 shows an exemplary embodiment of a substrate holder 1 according to the invention;

FIGS. 3a and 3b show perturbing effects in the prior art, which the invention counteracts.

### DETAILED DESCRIPTION

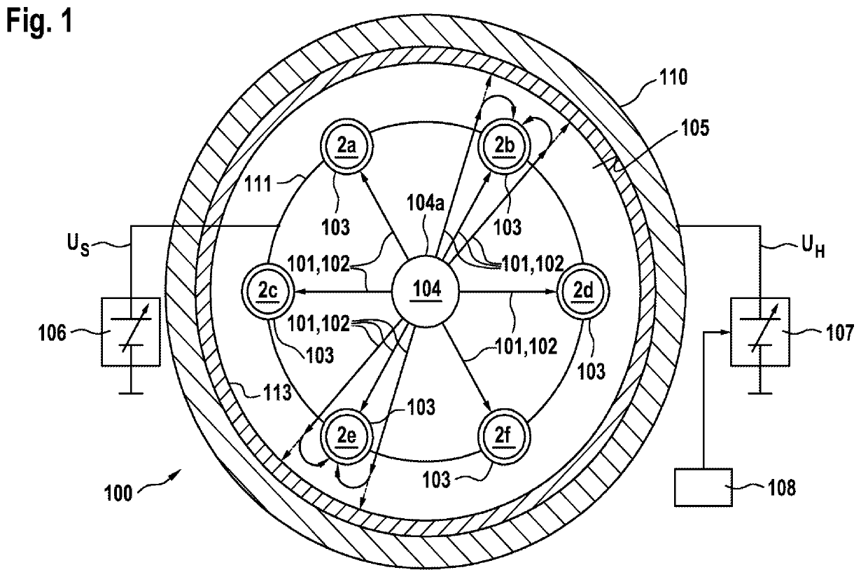

FIG. 1 shows an exemplary embodiment of a coating system 100 in plan view. The coating system 100 comprises a vacuum container 110, at the center of which a plasma with a plasma boundary layer 104a is arranged as an ion source 104. The substrates 2a-2f to be coated are electrically connected to one another by means of a ring line 111, and a potential U_{S} is applied to them by the first voltage source 106. This potential U_{S} has an attractive effect on the ions 101, 102 from the ion source 104.

In order to clean the substrates 2a-2f, the ion source is adjusted in such a way that it only emits argon ions. The argon ions 101 ablate impurities from the substrates 2a-2f. Subsequently, the ion source 104 is adjusted in such a way that it also emits ions 102 of the actual coating material 103. The coating material 103 is deposited on the substrates 2a-2f. The substrates 2a-2f are held by the substrate holder 1 in the vacuum container 110. The substrate holders 1 are covered by the substrates 2a-2f in the perspective selected in FIG. 1, and are therefore not indicated.

The inner wall of the vacuum container 110 forms a secondary surface 105, toward which ions 101, 102 that miss the substrates 2a-2f move. This secondary surface 105 is provided with an insulating covering 113, the thickness of which is shown greatly exaggerated in FIG. 1. Furthermore, a potential U_{H} is applied to the secondary surface 105 by means of the second voltage source 107. This potential U_{H} is then continuously tracked by the controller 118 in such a way that, on the one hand the potential U_{S} is always lower than the potential U_{H} as seen by the ions 101, 102, and on the other hand the potential U_{H} is always repulsive as seen by the ions 101, 102.

The insulating covering 113 and the potential U_{H} together have the effect that the ions 101, 102 that miss the substrates 2a-2f are at least partially deviated in the direction of the substrates 2a-2f. The trajectory that the deviated ions 101, 102 would follow without the deviation is indicated by dashes.

During the cleaning of the substrates 2a-2f, the deviation on the one hand has the effect that less material is ablated from the secondary surface 105 and deposited on the substrates 2a-2f. On the other hand, the entire surface of the substrate 2a-2f is respectively reached, and not only the subregions which lie in direct line of sight with the ion source 104.

During the actual coating, the deviation correspondingly has the effect that the coating material 103 is respectively deposited on the entire surface of the substrate 2a-2f, and no subregions remain uncoated. Such defects could, for example in wear protection layers, lead to increased wear occurring and the component failing prematurely.

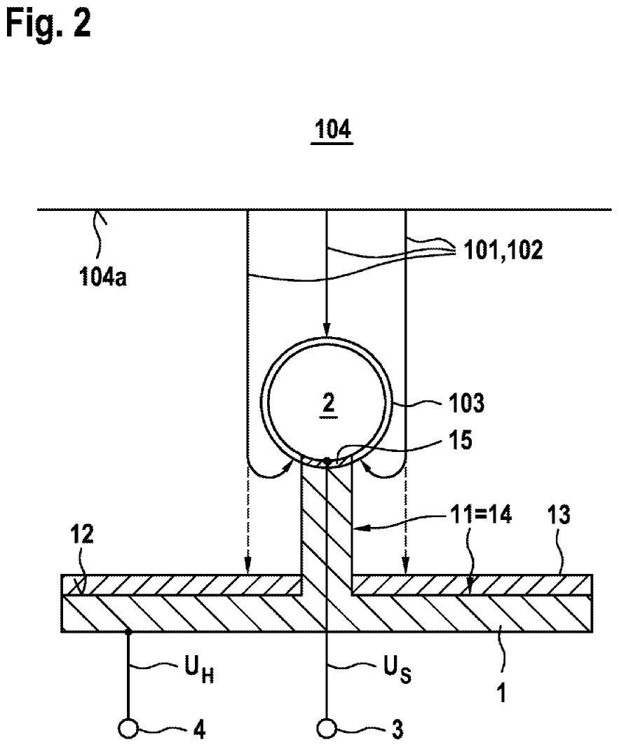

FIG. 2 shows an exemplary embodiment of a substrate holder 1 according to the invention. The substrate holder 1 has a first contact 3, by means of which a potential U_{S} can be applied to the substrate 1. In addition, its electrically conductive surface 11 has a charging region 12, which is provided with an insulating covering 13. The entire surface 11 of the substrate holder 1 can furthermore have the potential U_{H} applied to it by means of a second contact 4, and to this extent also serves as an electrode region 14. In order to illustrate the effect, FIG. 2 indicates the ion source with the plasma boundary layer 104a as well as the trajectories of the ions 101, 102, including their deviation in the direction of the substrate 2. The substrate 2 is insulated from the substrate holder 1 by means of an insulating intermediate piece 15 on the substrate holder 1, so that the potential U_{S} is not short-circuited to the potential U_{H}.

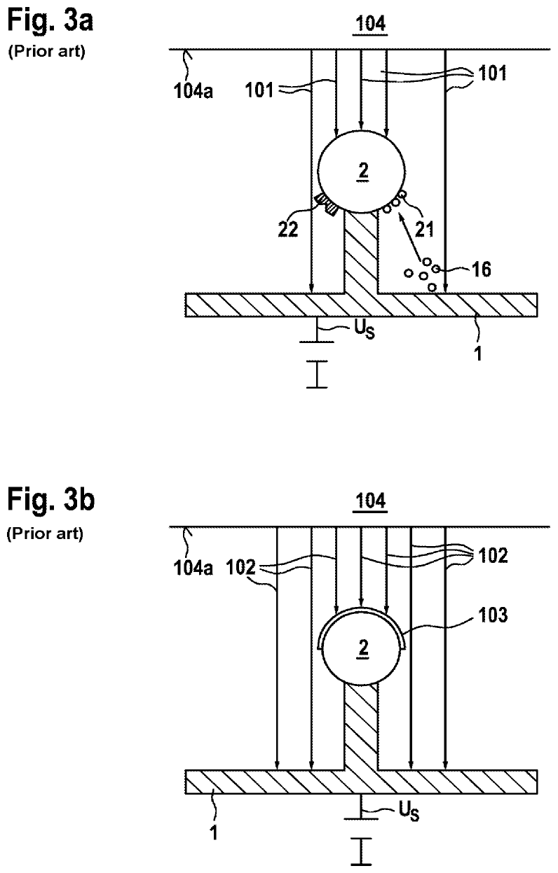

FIG. 3 illustrates the perturbing effects in the prior art, which the invention counteracts.

FIG. 3a shows the previous situation during the cleaning of the substrate 2. From the ion source 1, gas ions 101 are accelerated in the direction of the substrate 2, which is at the potential U_{S}. Since the substrate 2 is electrically conductively connected to the substrate holder 1, the substrate holder 1 is also at the potential U_{S} and attracts the gas ions 101 as strongly as the substrate 2 does. As a result, the gas ions 101 may remove extraneous atoms 16 from the substrate holder 1, which are deposited as impurities 21 on the substrate 2. Furthermore, the side of the substrate 2 facing away from the ion source 104 is not detected by the gas ions 101. Impurities 22 already present there are thus not removed by the cleaning of substrate 2 and may interfere with the application of the coating material 103.

FIG. 3b shows the previous situation during production of the coating from the coating material 103 on the substrate 2. The ions of the coating material 103 can reach only about half of the surface of the substrate 2. In order to coat the substrate 2 fully, it must for example be rotated.

1. A substrate holder (1) for mounting a substrate (2) in a coating system (100), in such a way that a surface (11) of the substrate holder (1) faces toward an ion source (104) of the coating system (100), the substrate holder comprising:
a first contact (3) for delivering a potential US to the substrate (2),
a charging region (12) on the surface (11) of the substrate holder (1) configured (13) to be chargeable by ions (101, 102) incident from the ion source (104) of the coating system (100).

2. A coating system (100) having
at least one ion source (104),
a first voltage source (106), which can be connected to a substrate (2) to be coated so that ions can be accelerated in the direction of the substrate (2) by an electrical potential US applied to the substrate (2) by the first voltage source (106), and
at least one secondary surface (11, 105), toward which ions (101, 102) that miss the substrate (2) move, configured (13, 113) to be chargeable by incident ions (101, 102).

3. The coating system (100) as claimed in claim 13, further comprising a controller (108) for the second voltage source (107) is provided, which is configured in order to track the potential UH to a change in the potential US, in such a way that the potential US is at a lower energy than the potential UH as seen by the ions (101, 102).

4. The coating system (100) as claimed in claim 13, further comprising a controller (108) for the second voltage source (107), which is configured to track the potential UH to (a) a change in properties of the ion reservoir (104), (b) to a change in the potential US, or both (a) and (b) in such a way that the potential UH is repulsive as seen by the ions (101, 102).

5. The coating system (100) as claimed in claim 2, further comprising a substrate holder (1) connected into the electrical connection between the first voltage source (106) and the substrate (2).

6. A method for operating a coating system (100), the method comprising:
accelerating ions in the direction of the substrate (2) by applying an electrical potential US to a substrate (2), and
applying a potential UH different to the potential US to at least one secondary surface (11, 105), toward which ions (101, 102) that miss the substrate (2) move.

7. The method as claimed in claim 6, wherein a potential UH is selected which has a repulsive effect on the ions (101, 102).

8. The method as claimed in claim 7, wherein a combination of potentials US and UH is selected, which deviates ions (101, 102) travelling in the direction of the secondary surface (11, 105) onto the substrate (2).

9. The method as claimed in claim 8, wherein the potential UH is varied in order to modify the position (21) at which the deviated ions (101, 102) strike the substrate (2).

10. (canceled)

11. A non-transitory computer-readable medium containing machine-readable instructions which, when they are executed on a computer with a coating system (100) connected thereto, cause the coating system to
accelerate ions in the direction of the substrate (2) by applying an electrical potential US to a substrate (2), and
apply a potential UH different to the potential US to at least one secondary surface (11, 105), toward which ions (101, 102) that miss the substrate (2) move.

12. A substrate holder (1) as claimed in claim 1, the substrate holder further comprising a second contact (4), by means of which a freely selectable potential UH different to the potential US is applied to an electrode region (14) on the surface (11) of the substrate holder (1).

13. The coating system (100) as claimed in claim 2, further comprising at least one second voltage source (107), which can be connected to the secondary surface (11, 105) so that a freely selectable potential UH different to the potential US can be applied to the secondary surface (11, 105)
